(19) United States
(12) Patent Application Publication
(10) Pub. No.: US 2003/0224619 A1
(43) Pub. Date: Dec. 4, 2003

(54) Method for low temperature oxidation of silicon

(76) Inventors: Yoshi Ono, Camas, WA (US); Ray Hill, Vancouver, WA (US); Mark A. Burgholzer, Amboy, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 10/164,924

(22) Filed: Jun. 4, 2002

(51) Int. Cl. H01L 21/31; H01L 21/469

(52) U.S. Cl. 438/771

(57) ABSTRACT

A method of low-temperature oxidation of a silicon substrate includes placing a silicon wafer in a vacuum chamber; maintaining the silicon wafer at a temperature of between about room temperature and 400° C.; introducing an oxidation gas in the vacuum chamber; dissociating the oxidation gas into O(1D) radical oxygen and irradiating the surface of the silicon wafer with a xenon excimer lamp generating light at a wavelength of about 172 nm to eject electrons from the surface of the silicon wafer and forming the reactive oxidizing species over the silicon wafer; and forming an oxide layer on at least a portion of the silicon wafer.

### RELATED APPLICATIONS This application is related to Serial No.______, filed______, for A Method of forming a high quality gate oxide at low temperatures.

### FIELD OF THE INVENTION

This invention relates to an apparatus and method for performing a fabrication step in the manufacture of integrated circuits on silicon, and specifically for performing a low temperature silicon oxidation for shallow trench isolation and for gate oxidation using a radical oxygen mechanism.

### BACKGROUND OF THE INVENTION

The conventional technique for the oxidation of silicon requires high temperatures, e.g., greater than 800° C., for long periods of time in oxidizing ambient such as O₂, N₂O, or NO. During such oxidation, the diffusion of elements occurs within and between the substrate and the oxidation tool, i.e., the mechanism used to hold the wafer. The environment must be tailored to accommodate such diffusion with high purity quartz components, graphite loading arms, and other components in the furnace and the furnace surfaces. The ability to perform oxidation at much lower temperatures and without a large investment in tool costs is a tremendous benefit to the semiconductor industry.

Prior art techniques use high quality and high purity quartz furnaces with heating elements capable of raising the tube temperature nearly to the melting point of silicon. Typical oxidation processes occur at between about 900° C. to 1100° C., in the presence of O₂, N₂O, or NO. Silicon wafers are pushed in the furnace and pulled out at a lower temperature, typically about 700° C., using a graphite loader which holds the quartz boats which hold the wafers. The requirements for the purity and quality make this a relatively expensive process.

An efficient method of oxidizing silicon at low temperatures for manufacturing purposes currently does not exist. There are known methods of oxidizing silicon at low temperatures, such as electron cyclotron resonance (ECR) plasma oxidation, Togo et al., Impact of Radical Oxynitridation on Characteristics and Reliability of sub-1.5 nm Thick Gate Dielectric FETs with Narrow Channel and Shallow Trench Isolation, IEDM Technical Digest 2001, p. 813, and Togo et al., Controlling Base SiO₂ Density of Low Leakage 1.6 nm Gate SiON for High Performance and Highly Reliable n/pFETs, Symposium on VLSI Technology 2001, T07A_{—}3, or plasma oxidation with a radial slot line antennae, Saito et al., Advantage of Radical Oxidation for Improving Reliability of Ultra-Thin Gate Oxide, 2000 Symposium on VLSI Technology, T18-2, 2000. The methods described in the forgoing publications produce large quantities of ions, electron and photons, in addition to the radicals which can damage the silicon surface and degrade the oxide quality. Though the references claim good quality oxide formation, none of these methods has been adopted for production-line use at this time. The radiation-induced radical oxidation process which performs an oxidation without substantial ion formation is expected to be better. A variation of the Saito et al. technique is described in Hirayama et al., Low Temperature Growth of High-Integrity Silicon Oxide Films by Oxygen Radical Generated in High Density Krypton Plasma, IEDM Tech. Dig. p249, 1999. All of the foregoing references require traditional, non-reactive chambers and specialized wafer holding tools.

### SUMMARY OF THE INVENTION

A method of low-temperature oxidation of a silicon substrate includes placing a silicon wafer in a vacuum chamber; maintaining the silicon wafer at a temperature of between about room temperature and 400° C.; introducing an oxidation gas in the vacuum chamber; dissociating the oxidation gas into O(1D) radical oxygen and irradiating the surface of the silicon wafer with a xenon excimer lamp generating light at a wavelength of about 172 nm to eject electrons from the surface of the silicon wafer and forming the reactive oxidizing species over the silicon wafer; and forming an oxide layer on at least a portion of the silicon wafer.

It is an object of the invention to provide a method for the low temperature oxidation of silicon which does not introduce contaminants into the silicon wafer or oxide layers formed thereon.

Another object of the invention is to provide for low temperature oxidation of silicon in conventional furnaces without costly retrofitting.

A further object of the invention is provide a method of forming an oxide layer on a silicon substrate at a temperature below 400° C. and improving the oxide quality for MOSFET gate oxide applications with a rapid thermal anneal at a temperature below 750° C.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a schematic representation of the apparatus used in the method of the invention.

FIG. 2 is a graph depicting oxide thickness as a function of chuck temperature.

### DETAILED DESCRIPTION OF THE PREFERRED EMBODIMENTS

Using the method of the invention, silicon may be oxidized in almost any vacuum chamber capable of base pressures of up to 1×10⁻⁵ Torr. The materials of the vacuum chamber may be fabricated of any of a number of materials, including anodized aluminum, stainless steel, Teflon®, glass, ceramics, as well as quartz and graphite. Thus, conventional vacuum chambers may be used without costly retrofitting, and newly constructed chambers do not need to be fabricated of costly, non-reactive materials. Temperature tolerances are not a major concern because oxidation may be conducted at temperatures as low as room temperature, while significant impurity diffusion does not occur until temperatures reach about 600° C.+.

The method of the invention is to generate large quantities of a reactive oxygen species, which is suspected to be radical oxygen atoms in the O(1D) metastable state, or O⁻ ions. It is known that O(1D) can be produced by photodissociation of N₂O, i.e., N₂O irradiated with light wavelengths of less than 195 nm produces O(1D) in a simple photodissociation step, which results in N₂ and O. Because the O(1D) state is of higher energy than the ground, O(3P), state, oxygen in the O(1D) state results in faster oxidization of silicon, and results in a much more efficient oxidation process. The formation of O(1D) can also originate from O₂, O₃, NO, though the necessary photon wavelength will be different in each case. The negative ion species O⁻ can be formed through the dissociative electron attachment from N₂O, O₂, or O₃. A low kinetic energy electron in collision with a molecule such as N₂O forms a temporary negative ion N₂O, which then dissociates to form N₂ and O⁻.

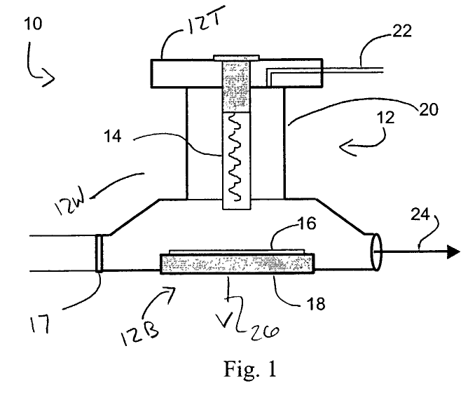

The apparatus of the method of the invention is depicted in FIG. 1, generally at 10. Apparatus 10 includes a vacuum chamber 12, having a xenon excimer lamp 14 located therein, which lamp emits light at a wavelength of about 172 nm, or 7,21 eV in energy, with a power of between about 3 mW/cm² to 20 mW/cm². Lamp 14 is placed in vacuum chamber 12 above the surface of a silicon wafer 16 that is to be at least partially oxidized. Wafer 16 may be patterned to provide oxidation of specific regions thereof, or the entire wafer may be oxidized, thus, wafer 16 may comprise a silicon substrate. Wafer 16 is placed in chamber 12 through a load-lock 17. Wafer 16 is held in place in a wafer-holding chuck 18. The materials used to construct this vacuum chamber may be anodized aluminum, stainless steel, quartz, glass, ceramics and other materials not normally used in silicon oxidation technology. Chamber 12 has a Teflon® top surface 12T, and anodized aluminum walls 12W and bottom 12B. Lamp 14 is located in a ceramic cylinder 20. Oxidation gas, N₂O being one possible oxidation gas, is introduced into chamber 12 through an inlet manifold 22, and is removed from chamber 12 by a throttle valve and turbo pump 24. Lamp 14 is a source for producing a large flux of photons. The photons are believed to initiate the oxidation of silicon through 1) dissociation of the oxidation gas to form O(3P) and O(1D) radicals and/or 2) ejection of photoelectrons from the silicon surface, which electrons reacts with the oxidation gas to form O⁻ ions in a region adjacent to the silicon wafer.

In the case where of an oxidation performed at less than 400° C., the impurity diffusion is negligible. This allows oxidation on things such as plastic substrates. The xenon excimer lamp is a relatively low-cost, commercially available product, e.g., Xeradex™ lamp produced by Osram Sylvania.

During oxidation, a steady flow of gas, such as N₂O, is introduced into the chamber and the pressure is controlled by the throttle valve located between the chamber and the pump system. Some of the N₂O is dissociated by the photons from lamp 14, generating the radical oxygen atom O(1D) and N₂ as the main byproducts. The photons from lamp 14 also impinge on the surface of wafer 16, causing it to eject photoelectrons with and energy of about 2 eV. These low energy electrons may be captured by N₂O to form N₂ and O⁻. The radical oxygen and/or negative oxygen ions then react with the silicon wafer to produce a silicon oxide region. The wafer sits on chuck 18, which is capable of generating temperatures therein of up to about 400° C. Because of the design of chuck 18, the wafer may not reach the same temperature as the chuck. The temperature offset maybe as high as 100° C. to 150° C. at a chuck set point of 400° C. Thus, wafer 16 may be held at a temperature of between about room temperature and 400° C. during oxidation, but more likely, wafer 16 will be at a temperature of between room temperature and 300° C.

A method of low-temperature oxidation of a silicon substrate includes placing a silicon wafer in a vacuum chamber; maintaining the silicon wafer at a temperature of between about room temperature and 600° C.; introducing an oxidation gas in the vacuum chamber including introducing an oxidation gas taken from the group of oxidation gases consisting of N₂O, O₂, NO. and O₃; a xenon excimer lamp generating light at a wavelength of about 172 nm with a power of between about 3 mW/cm² to 20 mW/cm² irradiates the volume of oxidizing gas and the wafer surface, The excimer lamp irradiation of the gaseous O₂ in the chamber generates O₃, which is adsorbed preferentially over O₂ on the surface of the wafer. The radiation on the wafer 1) photodissociates the O₃ to form O₂ and O radicals, 2) ejects low energy photoelectrons from the surface which is captured by the O₃, to form O₂ and O⁻ in a dissociative electron attachment reaction, and 3) breaks Si—Si bonds at the interface of the growing oxide film facilitating the further growth of the oxide. Both the O radical and the O⁻ ion are highly reactive with the silicon. A rapid thermal anneal must be performed after the oxide growth to recrystallize the damaged silicon layer at the oxide interface. This requires a temperature of between about 600° C. to 750° C. for between about one to ten minutes. In the case of N₂O, the adsorbed molecules can photodissociate into either N₂+O radical or NO+N. This can lead to small nitrogen content in the final oxide film. Photoelectrons from the surface can dissociatively attach electrons to form N₂+O⁻. Again, the photons also break the Si—Si bonds to facilitate oxide formation from the reactive O radicals and O⁻ ions and a rapid thermal anneal is required to complete this oxide.

It is an object of the invention to form an oxide layer on a silicon substrate at a temperature below 400° C. and improving the oxide quality for MOSFET gate oxide applications with a rapid thermal anneal at a temperature below 750° C. Thus, the wafer, after oxidation, is annealed in an inert atmosphere for between about one minute to ten minutes at a temperature of between about 600° C. to 750° C. to recrystallize the silicon.

A small positive potential is sufficient to significantly slow the oxidation. By experimentation, it was established that a small negative potential was sufficient to accelerate oxidation. A silicon wafer was electrically floated (insulated) from the chuck bias, which builds up a positive potential during the ejection of photoelectrons. When the silicon wafer is electrically grounded, creating a neutral potential, the oxidation process was observed to increase. Application of a negative potential increased both the photoelectron energy and quantity, both of which can contribute to enhance the oxidation rate.

For a standard ten minute oxidation process, a layer of oxide having a thickness of 31 Å was formed when the silicon wafer was grounded to the wafer chuck. An oxide layer of 15 Å thickness was formed under the same time and conditions when the silicon wafer was insulated from the wafer chuck. The probability of an O₃ reaction an electron to form O2 and O⁻ is known to increase with the electron energy until the electron energy reaches 9 eV. When the silicon wafer is grounded, the electron energy is only 2.3 eV. A negative bias of about 5-10 volts, 26, produced an adequate negative potential to accelerate the oxide grow, allowing the ten minute oxidation process to be completed in between about three to four minutes.

The amount of the oxygen in the (1D) state is dictated by the amount of N₂O introduced into the chamber, the intensity of the light from the excimer lamp, and the duration of the existence of O(1D) near the wafer surface. The longer the exposure to this environment, the thicker the resulting oxide.

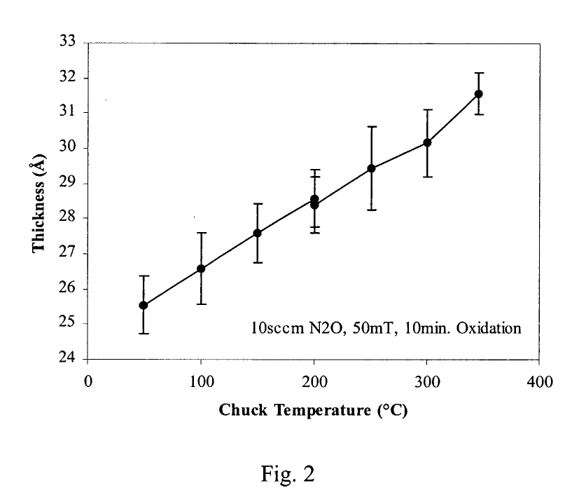

The oxidation of silicon with the O(1D) radical is not highly temperature dependent, and a substantial oxide layer may be generated even at room temperature. At elevated temperatures, a small enhancement to the oxidation rate is seen. The temperature dependence of a ten minute oxidation is shown in FIG. 2.

The quenching of the O(1D) state or of O⁻ by N₂O, or the byproducts of N₂O photodissociation, do not appear to affect the oxidation. For this reason, the proximity of the lamp to the wafer is not particularly critical. To achieve optimum oxidation conditions, the pressure and the flow of gas need to be varied. For the configuration of the apparatus of the invention, a chamber pressure of between about 40 mTorr. to 90 mTorr., with a gas flow rate of between about 2 sccm to 50 sccm is adequate.

The configuration of lamp 14 placement with respect to the wafer in the vacuum chamber is not particularly critical. An important design consideration, however, is to illuminate the volume of the chamber that is filled with a small amount of N₂O, so that the dissociation byproducts can interact with the wafer surface so that electrons may be ejected form the wafer surface. Based on this consideration, lamp 14 can be placed in any orientation with respect to the wafer. The net flow of gas should be such that the wafer is downstream from both the gas inlet and lamp 14. Introducing an oxidation gas in the vacuum chamber includes introducing a gas taken from the group of oxidation gases consisting of N₂O, NO, O₂, and O₃ into the vacuum chamber, which may be dissociated by introduction of appropriate photons.

With the advancement in excimer lamp technology, the use of alternate wavelengths is possible. Other excimer lamp systems can produce light at 126 nm, 146 nm, 222 nm, and 308 nm, however, it is not likely that these are as efficiently as the xenon excimer at 172 nm.

Thus, a method and system for low temperature oxidation of silicon has been disclosed. It will be appreciated that further variations and modifications thereof may be made within the scope of the invention as defined in the appended claims.

We claim:

1. A method of low-temperature oxidation of a silicon substrate comprising:
placing a silicon wafer in a vacuum chamber;
maintaining the silicon wafer at a temperature of between about room temperature and 400° C.;
introducing an oxidation gas in the vacuum chamber;
irradiating the silicon wafer surface with a xenon excimer lamp generating light at a wavelength of about 172 nm to eject electrons from the silicon wafer surface and dissociating the oxidation gas to form a reactive oxygen species over the silicon wafer; and
forming an oxide layer on at least a portion of the silicon wafer.

2. The method of claim 1 which further includes maintaining the vacuum chamber at a pressure of between about 40 mTorr. and 90 mTorr.

3. The method of claim 1 wherein said introducing an oxidation gas in the vacuum chamber includes providing a gas flow rate of between about 2 sccm and 50 sccm.

4. The method of claim 1 wherein said introducing an oxidation gas in the vacuum chamber includes introducing N₂O into the vacuum chamber.

5. The method of claim 1 which includes, during said irradiating, applying a negative potential of between about five to ten volts to the silicon wafer.

6. The method of claim 1 which includes, after said forming, annealing the silicon wafer and oxide layer in an inert atmosphere for between about one to ten minutes at a temperature of between about 600° C. to 750° C.

7. A method of low-temperature oxidation of a silicon substrate comprising:
placing a silicon wafer in a vacuum chamber;
maintaining the silicon wafer at a temperature of between about room temperature and 400° C.;
introducing an oxidation gas in the vacuum chamber;
irradiating the silicon wafer surface with a xenon excimer lamp generating light to eject electrons from the silicon wafer surface and dissociating the oxidation gas to form a reactive oxygen species over the silicon wafer; and
forming an oxide layer on at least a portion of the silicon wafer.

8. The method of claim 7 which further includes maintaining the vacuum chamber at a pressure of between about 40 mTorr. and 90 mTorr.

9. The method of claim 7 wherein said introducing an oxidation gas in the vacuum chamber includes providing a gas flow rate of between about 2 sccm and 50 sccm.

10. The method of claim 7 wherein said introducing an oxidation gas in the vacuum chamber includes introducing a gas taken from the group of oxidation gases consisting of N₂O, NO, O₂, and O₃ into the vacuum chamber.

11. The method of claim 7 wherein said generating light includes generating light at a wavelength of about 172 nm.

12. The method of claim 7 which includes, during said irradiating, applying a negative potential of between about five to ten volts to the silicon wafer.

13. The method of claim 7 which includes, after said forming, annealing the silicon wafer and oxide layer in an inert atmosphere for between about one to ten minutes at a temperature of between about 600° C. to 750° C.

14. A method of low-temperature oxidation of a silicon substrate comprising:
placing a silicon wafer in a vacuum chamber;
maintaining the silicon wafer at a temperature of between about room temperature and 400° C.;
introducing N₂₀ oxidation gas in the vacuum chamber;
irradiating the silicon wafer surface with a xenon excimer lamp generating light at a wavelength of about 172 nm to eject electrons from the silicon wafer surface and dissociating the oxidation gas to form a reactive oxygen species over the silicon wafer, and applying a negative potential of between about five to ten volts to the silicon wafer;
forming an oxide layer on at least a portion of the silicon wafer; and
annealing the silicon wafer and oxide layer in an inert atmosphere for between about one to ten minutes at a temperature of between about 600° C. to 750° C.

15. The method of claim 14 which further includes maintaining the vacuum chamber at a pressure of between about 40 mTorr. and 90 mTorr.

16. The method of claim 14 wherein said introducing an oxidation gas in the vacuum chamber includes providing a gas flow rate of between about 2 sccm and 50 sccm.
